(19) United States
(12) Patent Application Publication
(10) Pub. No.: US 2025/0062228 A1
(43) Pub. Date: Feb. 20, 2025

(54) SEMICONDUCTOR DEVICE

(71) Applicant: Samsung Electronics Co., Ltd., Suwon-si (KR)

(72) Inventors: Sanghyun PARK, Suwon-si (KR); Gyuhee PARK, Suwon-si (KR); Inji LEE, Suwon-si (KR); Hase NAOKI, Suwon-si (KR)

(73) Assignee: Samsung Electronics Co., Ltd., Suwon-si (KR)

(21) Appl. No.: 18/657,084

(22) Filed: May 7, 2024

(30) Foreign Application Priority Data
Aug. 17, 2023 (KR) 10-2023-0107673

(51) Int. Cl. H01L 23/528; H01L 23/522; H01L 23/532; H10B 12/00

(52) U.S. Cl. CPC H01L 23/5283; H01L 23/5226; H01L 23/528; H01L 23/53219; H01L 23/53228; H10B 12/315; H10B 12/50

(57) ABSTRACT

A semiconductor device may include a substrate including devices; a lower insulating layer on the substrate; a lower wiring layer on the lower insulating layer and electrically connected to the devices; a first upper insulating layer on the lower insulating layer; an upper contact penetrating through the first upper insulating layer and connected to the lower wiring layer, an upper wiring layer on the first upper insulating layer and connected to the upper contact; and a second upper insulating layer on the first upper insulating layer and covering the upper wiring layer. The upper wiring layer may include an aluminum alloy and 0.01-3 wt % of the aluminum alloy may be at least one dopant among Zn, Ni, V, and Cr. A balance of the aluminum alloy may include Al.

### CROSS-REFERENCE TO RELATED APPLICATION(S)

This application claims benefit of priority to Korean Patent Application No. 10-2023-0107673 filed on Aug. 17, 2023 in the Korean Intellectual Property Office, the disclosure of which is incorporated herein by reference in its entirety.

### BACKGROUND

Example embodiments of the present disclosure relate to a semiconductor device including a wiring structure.

Generally, to reduce RC delay of wirings due to parasitic capacitance between wirings, a low-K material may be used as an interlayer insulating layer. However, as a semiconductor device has been highly integrated, wirings may be formed in an insulating layer, which may include a low-K material, and wiring defects may occur.

### SUMMARY

An example embodiment of the present disclosure provides a semiconductor device including a wiring structure having reliability.

According to an example embodiment of the present disclosure, a semiconductor device may include a substrate including devices; a lower insulating layer on the substrate; a lower wiring layer on the lower insulating layer and electrically connected to the devices; a first upper insulating layer on the lower insulating layer; an upper contact penetrating through the first upper insulating layer and connected to the lower wiring layer; an upper wiring layer on the first upper insulating layer and connected to the upper contact; and a second upper insulating layer on the first upper insulating layer and covering the upper wiring layer. The upper wiring layer may include an aluminum alloy and 0.01-3 wt % of the aluminum alloy may be at least one dopant among Zn, Ni, V, and Cr. A balance of the aluminum alloy may include Al.

According to an example embodiment of the present disclosure, a semiconductor device may include a substrate including a memory cell region and a peripheral circuit region; capacitors on the memory cell region of the substrate; peripheral transistors on the peripheral circuit region of the substrate; an interlayer insulating layer covering the capacitors and the peripheral transistors on the substrate; lower contacts in the interlayer insulating layer, the lower contacts electrically connected to the capacitors and the peripheral transistors; a lower insulating layer on the interlayer insulating layer; a lower wiring layer on the lower insulating layer and electrically connected to the lower contacts; a first upper insulating layer on the lower insulating layer; an upper contact penetrating through the first upper insulating layer and connected to the lower wiring layer; an upper wiring layer on the first upper insulating layer and connected to the upper contact; and a second upper insulating layer on the first upper insulating layer and covering the upper wiring layer. The upper wiring layer may include an aluminum alloy and 0.01-3 wt % of the aluminum alloy may be at least one dopant among Zn, Ni, V, and Cr. A balance of the aluminum alloy may include Al.

According to an example embodiment of the present disclosure, a semiconductor device may include a substrate including devices; an interlayer insulating layer covering the devices on the substrate; a lower contact on the interlayer insulating layer and connected to the devices; a lower insulating layer on the substrate; a lower wiring layer on the lower insulating layer and connected to the lower contact; a first upper insulating layer on the lower insulating layer; an upper contact penetrating through the first upper insulating layer and connected to the lower wiring layer; a second upper insulating layer on the first upper insulating layer; and an upper wiring layer on the second upper insulating layer and connected to the upper contact. The upper wiring layer may include an aluminum alloy and 0.01-1.5 wt % of the aluminum alloy may be a first dopant among at least one of Zn and Ni. Also, 0.01-1.5 wt % of the aluminum alloy may be a second dopant among at least one of V and Cr. A balance of the aluminum alloy may include Al.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to an example embodiment of the present disclosure;

FIGS. 2A and 2B are cross-sectional diagrams illustrating a semiconductor device according to an example embodiment of the present disclosure, taken along lines I-I′ and II-II′ in FIG. 1, respectively;

FIG. 3 is an enlarged cross-sectional diagram illustrating portion A;

FIG. 4 is an image of grains of aluminum alloy forming an upper wiring layer illustrated in FIG. 3;

FIG. 5 is a graph illustrating a content of each dopant which may maintain α-phase Al and diffusion activation energy of each dopant in an Al matrix;

FIG. 6 is a graph illustrating a difference in atomic radius and a difference electronegativity between Al and each dopant;

FIG. 7 is a graph illustrating a segregation index of each dopant and resistivity of each dopant in an Al matrix;

FIGS. 8A to 8D are cross-sectional diagrams illustrating a process of forming an upper wiring layer according to an example embodiment of the present disclosure;

FIG. 9 is plan diagrams illustrating a cell region and a peripheral circuit region of a semiconductor device according to an example embodiment of the present disclosure;

FIG. 10 is cross-sectional diagrams illustrating a cell region of a semiconductor device in FIG. 9 taken along lines III-III′ and IV-IV′; and

FIG. 11 is a cross-sectional diagram illustrating a peripheral circuit region of a semiconductor device taken along line IIa-IIa′.

### DETAILED DESCRIPTION

Hereinafter, embodiments of the present disclosure will be described as follows with reference to the accompanying drawings.

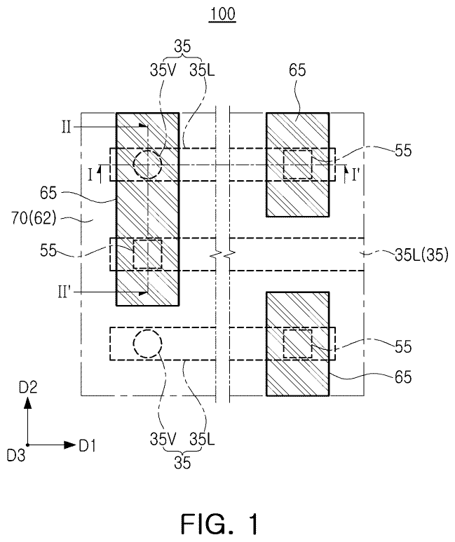

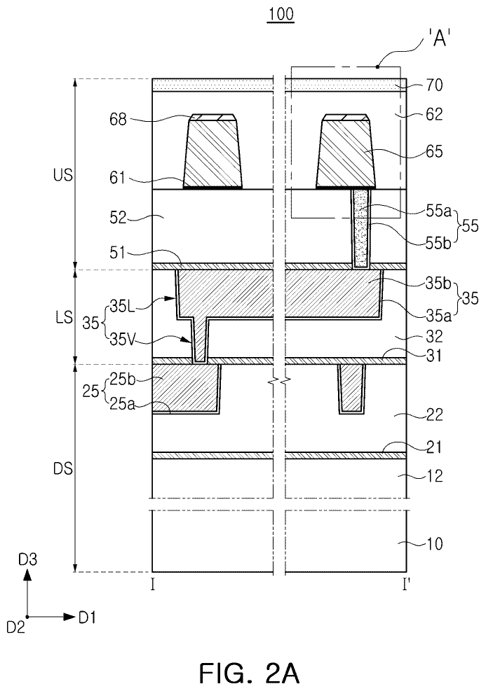

FIG. 1 is a plan diagram illustrating a semiconductor device according to an example embodiment. FIGS. 2A and 2B are cross-sectional diagrams illustrating a semiconductor device according to an example embodiment.

Referring to FIGS. 1, 2A and 2B, a semiconductor device 100 according to the example embodiment may include a device structure DS, a lower wiring structure LS on the device structure DS, and an upper wiring structure US on the lower wiring structure LS.

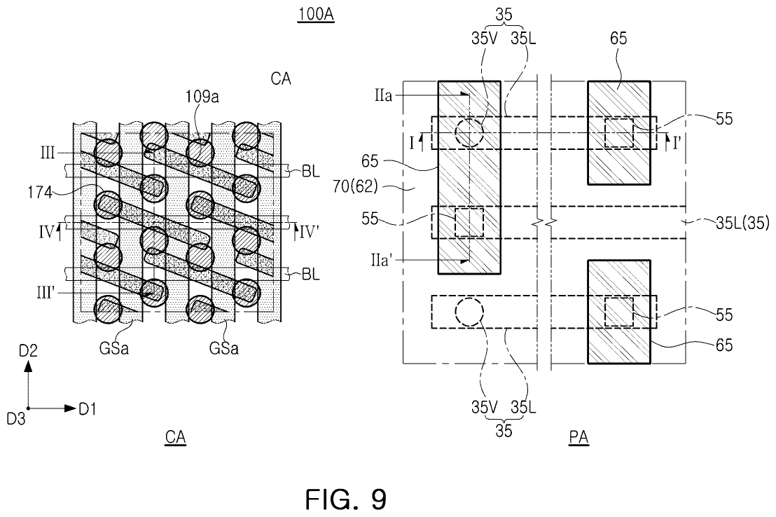

The device structure DS may include a substrate 10 including devices (not illustrated). The substrate 10 may be, for example, a semiconductor substrate such as silicon, germanium, or silicon-germanium. The devices may include transistors and/or circuits formed in the active region provided on the substrate 10. In some example embodiments, when the semiconductor device 100 is implemented as a memory device, the devices may include cell transistors included in a cell array, a data storage structure connected to the cell transistors, and peripheral transistors for driving the cell array (FIGS. 9 to 11).

The device structure DS may include an interlayer insulating layer 12 provided on the substrate 10 and a lower contact 13 penetrating through the interlayer insulating layer 12 and connected to the device. The lower contact may be provided as an electrical connection path with the lower wiring structure LS to be disposed on the device structure DS. The interlayer insulating layer 12 may include a low-K dielectric material. For example, interlayer insulating layer 12 may include boro-phosphosilicate glass (BPSG), tonen sazene (TOSZ), undoped silicate glass (USG), spin-on glass (SOG), flowable oxide (FOX), tetraethylortho silicate (TEOS), high density plasma chemical vapor deposition dielectric (HDP CVD insulating material), or hydrogen sisesquioxane (HSQ).

The lower contacts 13 may include a contact plug 13b and a barrier layer 13a covering a side surface and a bottom surface of the contact plug 13b. For example, the contact plug 13b may include at least one of tungsten (W), titanium (Ti), and tantalum (Ta). For example, the barrier layer 13a may include at least one of TiN and TaN.

In the example embodiment, a wiring structure including a lower wiring structure LS and an upper wiring structure US stacked in order may be provided on the device structure DS.

The lower wiring structure LS employed in the example embodiment may include first and second lower insulating layers 22 and 32, and first and second lower wiring layers 25 and 35 disposed in the first and second lower insulating layers 22 and 32, respectively. The lower wiring structure LS may further include a first etch stop layer 21 provided between the interlayer insulating layer 12 and the first lower insulating layer 22, and a second etch stop layer 31 provided between the first and second lower insulating layers 22 and 32.

The first and second lower wiring layers 25 and 35 may include wiring patterns 25L and 35L, and vias 25V and 35V extending downwardly from the wiring patterns 25L and 35L, respectively.

In the example embodiment, the first lower insulating layer 22 may cover the lower surface and the side surface of the wiring pattern 25L, and the via 25V of the first lower wiring layer 25 may penetrate through a portion of the first lower insulating layer 22 and the first etch stop layer 21 disposed on the lower surface of the wiring pattern 25L. Similarly, the second lower insulating layer 32 may cover a lower surface and a side surface of the wiring pattern 35L, and the via 35V of the second lower wiring layer 35 may penetrate through a portion of the second lower insulating layers 32 disposed on the lower surface of the wiring pattern 35L and the second etch stop layer 31. The first and second lower wiring layers 25 and 35 may be formed by a dual damascene process in the first and second lower insulating layers 22 and 32, respectively.

In the lower wiring structure LS, the first lower wiring layer 25 may be connected to lower contacts 13 through the via 25V thereof, and the second lower wiring layer 35 may be connected to the first lower wiring layer 25 through the via 35V thereof.

Each of the first and second lower wiring layers 25 and 35 may include wiring material layers 25b and 35b, and barrier material layers 25a and 35a covering side surfaces and bottom surfaces of the wiring material layers 25b and 35b. For example, the wiring material layers 25b and 35b may include Cu, and the barrier layers 25a and 35a may include at least one of Ti, Ta, TiN and TaN. For example, the first and second lower insulating layers 22 and 32 may include silicon oxide or a low-K dielectric material. In some example embodiments, each of the first and second lower insulating layers 22 and 32 may include SiCOH. The first and second lower insulating layers 22 and 32 may be formed of the same material, but an example embodiment thereof is not limited thereto, and a portion of the first and second lower insulating layers 22 and 32 may be formed of materials having different dielectric constants or different compositions. Also, each of the first and second etch stop layers 21 and 31 may include at least one of SiN, SiBN and SiCN. In the example embodiment, each of the number of lower insulating layers and the number of lower wiring layers may be two, but an example embodiment thereof is not limited thereto, and each of the number of lower insulating layers and the number of lower wiring layers may be varied, one or three or more, for example.

The upper structure US may be provided on the lower wiring structure LS. The upper structure US employed in the example embodiment may include first upper insulating layers 52 provided on the second lower insulating layer 32, upper contact 55 penetrating through the first upper insulating layers 52 and connected to the second lower wiring layer 35, an upper wiring layer 65 disposed on the first upper insulating layers 52 and connected to the upper contact, and second upper insulating layers 62 disposed on the first upper insulating layers 52 and covering the upper wiring layer 65. The upper structure US may further include an etch stop layer 51 between the second lower insulating layer 32 and the first upper insulating layer 52. In some example embodiments, a passivation layer 70 may be provided on the second upper insulating layers. For example, the passivation layer 70 may include an inorganic material such as silicon nitride (SiN) or an organic material such as polyimide.

Each of the first and second upper insulating layers 52 and 62 may include an insulating material having a higher dielectric constant than that of the first and second lower insulating layers 22 and 32. For example, each of the first and second upper insulating layers 32 and 52 may include boro-phosphosilicate glass (BPSG), tonen sazene (TOSZ), undoped silicate glass (USG), spin-on glass (SOG), flowable oxide (FOX), tetraethylortho silicate (TEOS), high density plasma chemical vapor deposition dielectric (HDP CVD insulating material), or hydrogen sisesquioxane (HSQ).

The upper contact 55 may penetrate through the first upper insulating layers 52 and the etch stop layer 51 and may be connected to the second lower wiring layer 32. The upper contact 55 may be electrically connected to the devices on the substrate 10 through the first and second lower wiring layers 25 and 35 and the lower contacts 13. The upper contact 55 may include a barrier layer 55a covering side surfaces and bottom surfaces of the contact plug 55b and the contact plug 55b. For example, the contact plug 55b may include at least one of tungsten (W), titanium (Ti), and tantalum (Ta). For example, the barrier layer 55a may include at least one of TiN and TaN. The upper contact 55 may include a conductive material other than that of the first and second lower wiring layers 25 and 35. For example, the wiring material layer of the first and second lower wiring layers 25 and 35 may include Cu, and the contact plug 55b may include W.

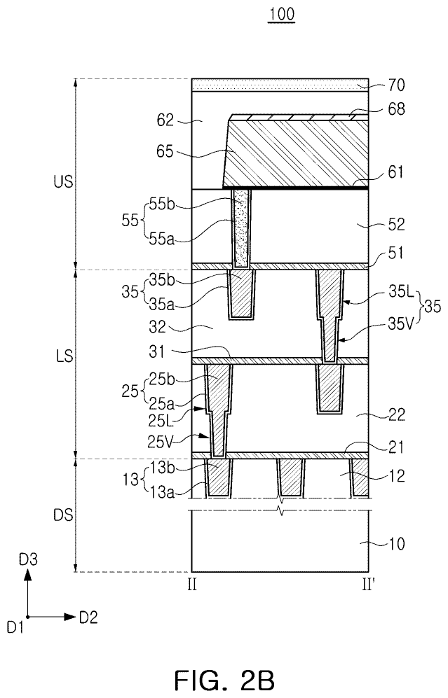

Referring to FIG. 3 together with FIGS. 2A and 2B, the upper wiring layer 65 may be connected to the upper contact 55 in the second upper insulating layers 62. A conductive bonding layer 61 may be disposed below the upper wiring layer 65. The conductive bonding layer 61 may be provided between the upper wiring layer 65 and the first upper insulating layers 52 to strengthen adhesion between the upper wiring layer 65 and the first upper insulating layers 62. For example, the conductive bonding layer 61 may be formed of Ti, Ta, Ru, TiN, TiSiN, TiAlx, TaN, or WN. An anti-reflective layer 68 may be provided on the upper wiring layer 65. The anti-reflective layer 68 may be provided for a lithography process of patterning the upper wiring layer 65. The anti-reflective layer 68 may be an organic or inorganic material. As in the example embodiment, when the anti-reflective layer 65 is an inorganic material, the anti-reflective layer 65 may remain. For example, the anti-reflective layer 65 may include TiN or TaN.

The upper wiring layer 65 employed in the example embodiment may include an aluminum (Al) alloy consisting of at least one dopant of Zn, Ni, V, and Cr, and a balance of Al. The dopants of Al alloy in the upper wiring layer 65 may greatly improve reliability of electro-migration (EM) and stress migration (SM).

Recently, due to shrinkage of the semiconductor device 100, among the properties of wirings employed in the semiconductor device 100, EM and SM properties may be an issue. In particular, as current density increases according to the microstructure of the upper wiring layer 65 including Al, EM properties may degrade. Also, after forming the upper wiring layer 65 (Al deposition and patterning) to improve properties of the semiconductor device 100, a grain size may increase during a process of injecting hydrogen, into the devices (e.g., transistors) of the semiconductor device 100 and a subsequent heat treatment process, residual stress may continuously increase, such that SM properties may also degrade.

In the example embodiment, a content of Al alloy for upper wiring layer 65 may be in a range in which a dopant such as Zn, Ni, V, Cr does not precipitate. The selected dopants may be contained in the Al alloy in the range of 0.01-3 wt %. In the process of forming the upper wiring layer 65, when a dopant is precipitated on the Al alloy target used when depositing the Al thin film for the upper wiring layer 65, charges may be concentrated in the precipitate during the sputtering process and sparks may occur, such that particles may be formed in the Al thin film. Accordingly, the final upper wiring layer 65 may be broken or a resistance defect may occur. Accordingly, the dopant employed in the example embodiments may be limited to an amount in which the Al thin film may be maintained in α-phase and does not precipitate.

In some example embodiments, the Al alloy of the upper wiring layer 65 may include a first dopant ED of at least one of Zn and Ni, and a second dopant SD of at least one of V and Cr. In the Al alloy of the upper wiring layer 65 according to the example embodiment, the first dopant may be contained at 0.01-1.5 wt %, and the second dopant may be contained at 0.01-1.5 wt %.

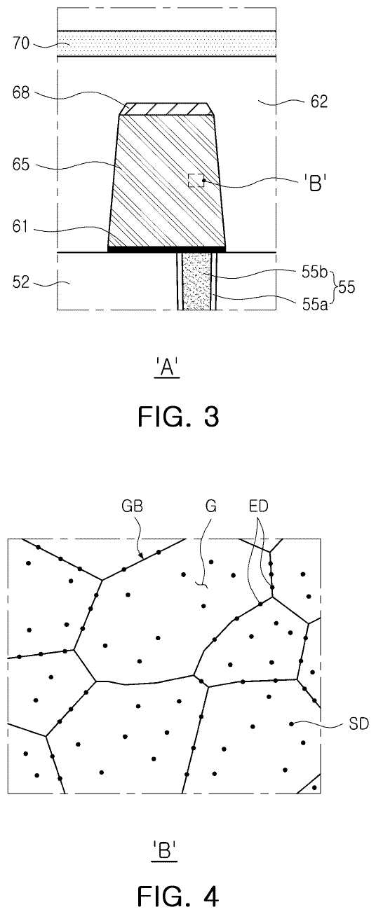

FIG. 4 is an image of grains of aluminum alloy forming an upper wiring layer illustrated in FIG. 3.

Referring to FIG. 4, the first dopant ED may be Zn and Ni, which may maintain the α-phase of Al without precipitating in the Al matrix and may have a strong tendency to segregate into the grain boundary GB to improve EM. The second dopant SD may include V and Cr which may maintain the α-phase of Al without precipitating in the Al matrix, and may be stably present in the grains G in the form of a substitutional alloy to improve SM. Since the second dopant SD has low diffusivity in Al, segregation into the grain boundary as in the first dopant ED may not occur.

In another example embodiment, to improve EM or SM required for the semiconductor device 100, the upper wiring layer 65 may be formed using an Al alloy including at least one of the first dopants ED or at least one of the second dopants SD.

As described above, the content not precipitating from Al may vary depending on the types of dopants, such that the contents may be varied depending on the types of selected dopants.

When at least one dopant includes Zn, the Al alloy may include 0.01-1 wt % of Zn. When at least one dopant includes Ni, the Al alloy may include 0.01-0.24 wt % of Ni. When at least one dopant includes V, the Al alloy may include 0.01-0.6 wt % of V. When at least one dopant is Cr, 0.01-0.7 wt % of Cr may be included.

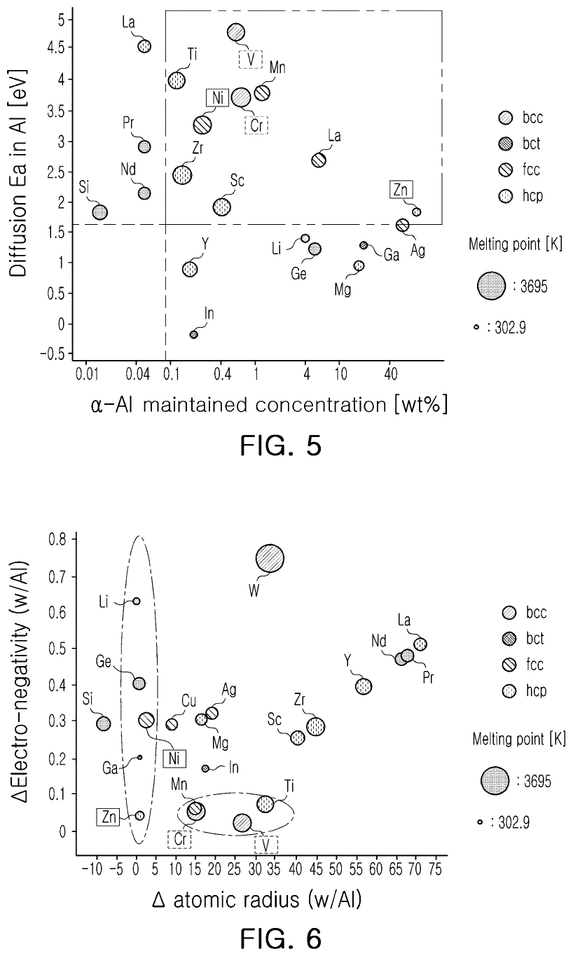

In the example embodiment, the dopant provided into the Al alloy to improve the EM and/or SM properties of the upper wiring layer may be selected in consideration of various conditions in FIGS. 5 to 7 in terms of precipitation of the dopant.

FIG. 5 is a graph illustrating a content of each dopant which may maintain α-phase Al and diffusion activation energy of each dopant in an Al matrix.

In the graph in FIG. 5, the X-axis may represent the content of each dopant which may maintain the α-phase of the Al matrix may be doped, and the Y-axis may represent the diffusion activation energy of each dopant in the Al matrix.

Referring to FIG. 5, to obtain the effect of using a dopant, dopants containable in an amount of approximately 0.01 wt % or more without precipitation may be selected from among the presented dopants. For example, such dopant (≥0.1 wt %), Ti, Zr, Ni, Sc, Cr, V, Mn, La, Zn, Ag, Y, In, Li, Ge, Mg, or Ga may be considered.

Also, as for poor EM reliability of the upper wiring layer, which is an Al alloy, since void nucleation and growth occur preferentially in regions in which the Al diffusion energy barrier is low, EM properties may be improved by lowering Al diffusivity. The diffusion activation energy of Al may be 1.4 eV in Al grains and may be 0.3-0.4 eV at the Al grain boundary. Also, when the conductive bonding layer 61 is Ti, the diffusion activation energy at the Al—Ti interfacial surface may be −3.9 eV, and may be −3.5 eV at the interfacial surface with the second upper insulating layers 62, that is, the Al—AlOx—SiOx interfacial surface. Accordingly, since the diffusion activation energy is lowest at the grain boundary, it may be necessary to lower diffusivity at the grain boundary.

The dopant for lowering diffusivity may need to have sufficient diffusion activation energy in Al. In the example embodiment, to improve EM, an element having diffusion activation energy of 1.5 eV or more in Al was selected as a dopant for Al alloy. Specifically, Ti, Zr, Ni, Sc, Cr, V, Mn, La, Zn, Ag, Si, La, Pr, and Nd were selected as primary candidate dopants.

Referring to the graph in FIG. 5, in terms of precipitation and EM properties improvement, the elements in the square box may be commonly considered as dopants (Ti, Zr, Ni, Sc, Cr, V, Mn, La, Zn, and Ag).

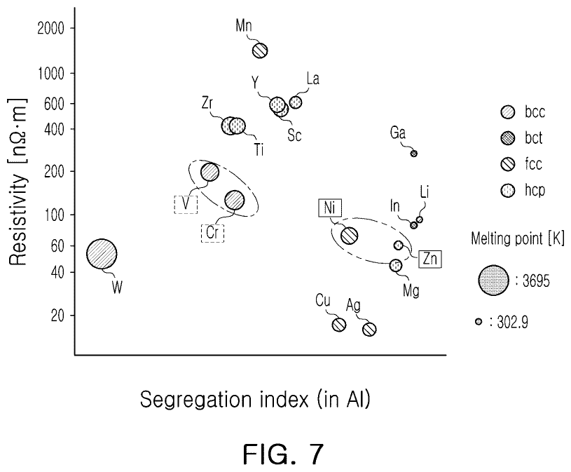

FIG. 6 is a graph illustrating a difference in atomic radius and a difference electronegativity between Al and each dopant.

Referring to FIG. 6, the radius and electronegativity of dopants are presented in terms of precipitation based on Hume-Rothery rules. In the example embodiment, as for the conditions for dopant according to Hume-Rothery rules, a material of which a difference in atomic radius was +5% or less, or a difference in electronegativity from Al was relatively small, a dopant which may be applied into an Al alloy, was considered.

The dopants satisfying the conditions of the difference in atomic radius may be considered Li, Ge, “Ni,” Ga, and “Zn,” and dopants satisfying the conditions of the difference in electronegativity may be considered “Cr,” “V,” “Mn,” “Ti.” Secondary candidate dopants commonly satisfying the condition in FIG. 6 (one of the two conditions) along with the condition in FIG. 5 may be Ni, Zn, Cr, V, Mn, and Ti.

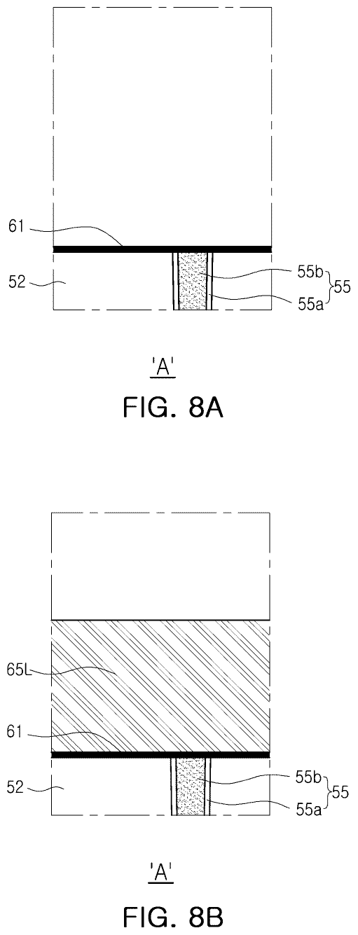

An alloy dopant was selected in terms of resistivity while distinguishing between dopants desirable to improve EM or SM according to the segregation tendency of the dopant. FIG. 7 is a graph illustrating a segregation index of each dopant and resistivity of each dopant in an Al matrix

As described with reference to FIG. 4, to improve EM, the dopant may need to be well segregated into the grain boundary, and to improve SM, the dopant may not need to be well segregated into the grain boundary. To select desirable dopants, a segregation index based on the difference in surface energy and difference in atomic volume with Al was provided.

The X-axis in FIG. 7 may represent the segregation index. A dopant with a large segregation index may have a strong tendency to segregate to a grain boundary (EM improvement), and a dopant with a small segregation index may have a strong tendency not to segregate to a grain boundary (SM improvement).

In the example embodiment, the dopant to improve EM reliability among the dopants provided into the upper wiring layer, which is an Al alloy, should not precipitate in Al, may need to maintain the α-phase of Al, and may need to be a material having a strong tendency to segregate to a grain boundary among materials having a diffusivity higher than Al diffusivity.

Also, among the dopants provided into the upper wiring layer, which is an Al alloy, the dopant to improve SM reliability should not precipitate in the Al matrix, may need to maintain the α-phase of Al, and may need to be stably present in the form of a substitutional alloy. To this end, diffusivity in Al may need to be low and the tendency of segregation to the grain boundary may also need to be low.

Referring to FIG. 7, among the previously selected secondary candidate dopants (Ni, Zn, Cr, V, Mn, and Ti), Ni and Zn may be selected as dopants disposed on the right side of the X-axis. Among the secondary candidate dopants (Ni, Zn, Cr, V, Mn, and Ti), Cr and V may be selected as dopants disposed on the left side of the X-axis. In the example embodiment, the other elements (Mn and Ti) of the secondary candidate dopants may not have a clear tendency for segregation index, and may also have relatively high resistivity, such that the elements may not be selected as appropriate dopants.

Consequently, the dopant for the Al alloy of the upper wiring layer may include at least one of Ni, Zn, Cr and V. The content of each dopant may include a minimum content (0.01 wt %) at the effective side surface, and an upper limit may be determined in terms of precipitation. The upper limit in terms of this precipitation may be determined by the precipitation content illustrated in FIG. 5.

Ni may be contained at 0.01-0.24 wt %. V may be contained at 0.01-0.6 wt %. Cr may be contained at 0.01-0.7 wt %. Zn may be contained at 0.01-1 wt %.

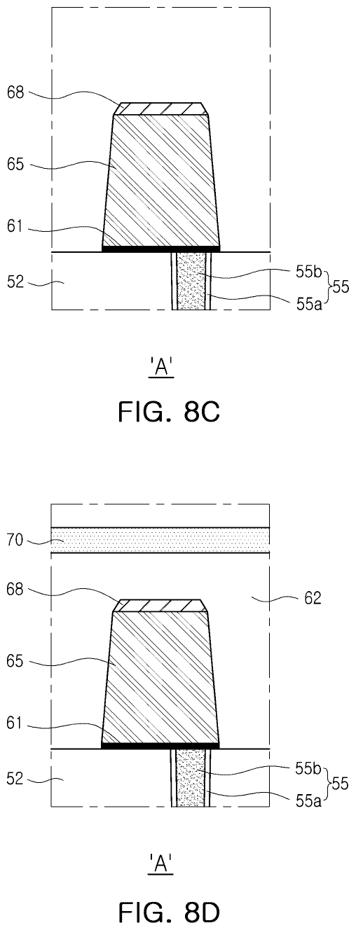

FIGS. 8A to 8D are cross-sectional diagrams illustrating a process of forming an upper wiring layer according to an example embodiment. The cross-sections may be of “A” region in FIG. 2A.

Referring to FIG. 8A, a conductive bonding layer 61 may be deposited on the first upper insulating layers 51.

The first upper insulating layers 51 may include an upper contact 55. The upper contact 55 may penetrate through the first upper insulating layers 52 and may be connected to the lower wiring layer (particularly, the second lower wiring layer (35 in FIG. 2A)) of the lower wiring structure (LS in FIG. 2A). The conductive bonding layer 61 may be provided to strengthen adhesion between Al alloy film 65L and first upper insulating layers 52 to be formed in the subsequent process. The conductive bonding layer 61 may include, for example, Ti, Ta, Ru, TiN, TiSiN, TiAlx, TaN, WN, or a combination thereof.

Thereafter, referring to FIG. 8B, The Al alloy film 65L for the upper wiring layer 65 may be deposited on the first upper insulating layers 52.

The deposition of Al alloy film 65L may be performed by physical vapor deposition (PVD) by sputtering an Al alloy target. The Al alloy target may have a composition corresponding to the Al alloy composition of the final upper wiring layer 65. The Al alloy target may include 0.01-3 wt % of a dopant of at least one of Zn, Ni, V, and Cr, and the balance of Al. In some example embodiments, the at least one dopant may include 0.01-1.5 wt % of the first dopant of at least one of Zn and Ni, and 0.01-1.5 wt % of the second dopant of at least one of V and Cr. In some embodiments, the Al alloy target may include 0.01-3 wt % of a dopant of at least one of Zn, Ni, V, and Cr, and the balance may include Al.

Thereafter, referring to FIG. 8C, the upper wiring layer 65 may be formed by patterning the Al alloy film 65L.

This patterning process may be performed by a photo-lithography process and a dry etch process. The conductive bonding layer portion disposed below the removed portion of Al alloy film 65 may also be removed. Before the photo-lithography process, an anti-reflective layer 68 may be further formed on the Al alloy film 65L. When the anti-reflective layer 68 is an inorganic material, for example, when the anti-reflective layer 68 includes TiN or TaN, the anti-reflective layer 68 may be patterned and may remain on the upper wiring layer 65.

As such, in the example embodiment, the upper wiring layer may be patterned after depositing the Al alloy film, such that the upper wiring layer may have a side surface inclined upwardly. The first and second lower wiring layers (25 and 35 in FIG. 2A) and the upper contact (55 in FIG. 2A) may be formed by a damascene process, such that the first and second lower wiring layers and the upper contact may have inclined side surfaces downwardly.

Thereafter, referring to FIG. 8D, second upper insulating layers 62 may be formed on the first upper insulating layers 52 to cover the upper wiring layer 55.

The second upper insulating layers 62 may be formed by spin coating. For example, the second upper insulating layers 62 may include a carbon or silicon-based spin-on hardmask (SOH) material, or silicon oxide or silicon nitride. Thereafter, an annealing process may be performed while supplying a passivation gas (H2, N2, Ar, or the like). The annealing process may be performed between 200-500° C. Here, the passivation gas may be injected after forming the wiring for channel trap passivation. In this process, as the small grain size of the upper wiring layer 65 may increase in subsequent annealing process, the residual stress may continuously increase, and due to the passivation gas, the tendency to brittle may increase. Despite the environment causing poor SM reliability, V and/or Cr among the Al alloys included in the upper wiring layer may have low diffusivity in Al and may be less likely to be segregated into grain boundaries, such that the elements may be present stably in a substitutional alloy form in the grain, and may greatly improve SM reliability.

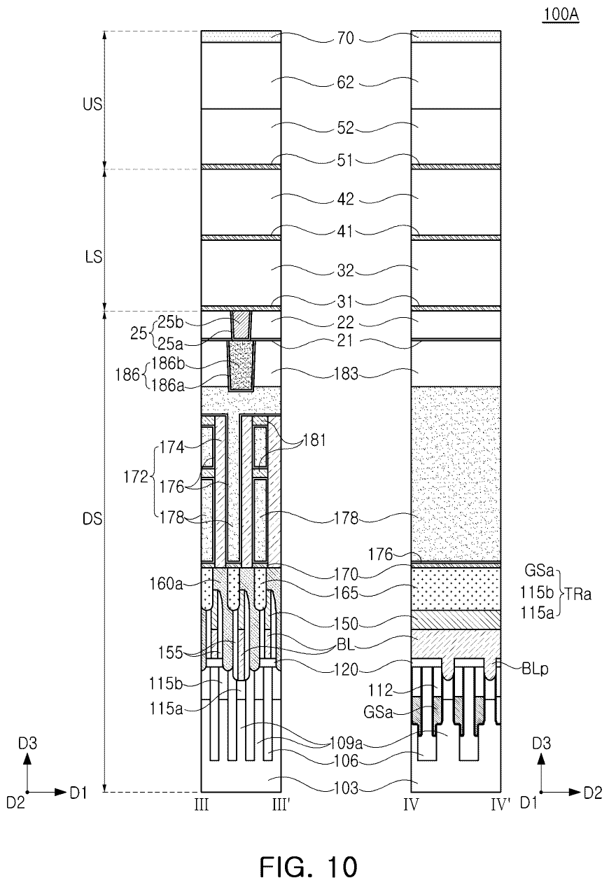

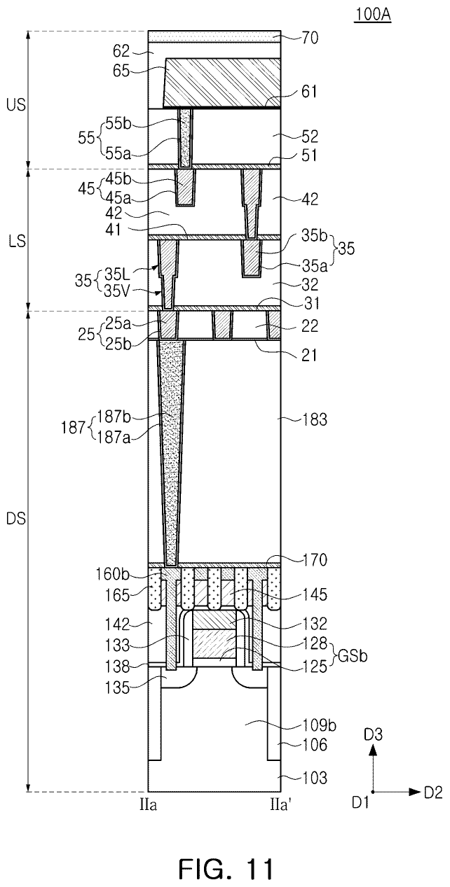

FIG. 9 is plan diagrams illustrating a cell region and a peripheral circuit region of a semiconductor device according to an example embodiment. FIG. 10 is cross-sectional diagrams illustrating a cell region of a semiconductor device in FIG. 9 taken along lines III-III′ and IV-IV′. FIG. 11 is a cross-sectional diagram illustrating a peripheral circuit region of a semiconductor device taken along line IIa-IIa′.

Referring to FIGS. 9, 10 and 11, the semiconductor device 100A according to the example embodiment may include a memory cell region CA and a peripheral circuit region PA in a horizontal direction. Also, similarly to the aforementioned example embodiment, the semiconductor device 100A may include a device structure DS, a lower wiring structure LS on the device structure DS, and an upper wiring structure US on the lower wiring structure LS in the vertical direction (e.g., D3 direction). The lower wiring structure LS and the upper wiring structure US in the peripheral circuit region may be configured the same or may include similar components unless otherwise indicated.

The device structure DS may include a substrate 103 and a device isolation layer 106 defining the active region. The device isolation layer 106 may define a cell active region 109a in the memory cell region CA and a peripheral active region 209b in the peripheral circuit region PA. The substrate 103 may be configured as a semiconductor substrate similar to substrate 10 described in the aforementioned example embodiment.

The cell active region 209a and the peripheral active region 209b may have a shape protruding from the substrate 103 in the vertical direction. The device isolation layer 206 may be formed as shallow trench isolation. The device isolation layer 206 may be formed of an insulating material such as silicon oxide and/or silicon nitride.

The device structure DS may include cell gate structures GSa buried in the cell active region 109a in the memory cell region CA and extending into the device isolation layer 106, and cell gate capping patterns 112 on the cell gate structures GSa. The cell gate structures GSa and the cell gate capping patterns 112 may be disposed in cell gate trenches intersecting the cell active region 109a and extending into the device isolation layer 106.

Each of the cell gate structures GSa may include a cell gate dielectric layer and a cell gate electrode of the cell gate dielectric layer. The cell gate electrode may be a wordline of a memory semiconductor device such as DRAM. The cell gate structures GSa may include wordlines.

Also, the device structure DS may further include a first source/drain region 115a and a second source/drain region 115b disposed in the cell active region 109a. The cell gate structure GSa and the cell source/drains SD may be included in the cell transistors TRa.

In the memory cell region CA, the device structure DS may include a cell active region 109a and buffer insulating layers 120 provided on the device isolation layer 106, a bitline BL provided on the buffer insulating layers 120 and including a plug portion BLp penetrating through the buffer insulating layers 120, a bitline capping layer 150 on the bitline BL, and a cell contact structures 160a disposed on both sides of the bitline BL. The cell contact structures 160a may have a pad portion extending onto the bitline capping layer 150. Also, the device structure DS may further include an insulating isolation structure 165 disposed between the pad portions of the cell contact structures 160a and extending downwardly, and insulating spacers 155 on the side surfaces of the bitline BL and the bitline capping layer 150.

The device structure DS may further include a peripheral transistor GSb (135) disposed in the peripheral circuit region PA. The peripheral transistor GSb (135) may include a peripheral gate structure GSb on the peripheral active region 109b and peripheral source/drain regions 135 in the peripheral active region 109b on both sides of the peripheral gate structure GSb. The peripheral gate structure GSb may include a peripheral gate dielectric layer 125 and a peripheral gate electrode 128 on the peripheral gate dielectric layer 125.

The device structure DS may include a peripheral gate capping layer 132 on the peripheral gate structure GSb, a gate spacer 133 on a side surface of the peripheral gate structure GSb, the peripheral transistor GSb (135), an insulating liner 138 covering the gate spacer 133 and the peripheral gate capping layer 132, and the peripheral interlayer insulating layer 142 on the insulating liner 138.

The device structure DS may further include a peripheral capping layer 145 on the peripheral interlayer insulating layer 142, and a peripheral contact structure 160b penetrating through the peripheral capping layer 145 and the peripheral interlayer insulating layer 142 and electrically connected to the peripheral transistors GSb and 135. The peripheral contact structure 160b may include a pad portion disposed on a level higher than a level of the peripheral capping layer 145. The insulating isolation structure 165 may define a side surface of the pad portion of the peripheral contact structure 160b and may extend downwardly.

The peripheral contact structure 160b may further include cell contact structures 160a, a peripheral contact structure 160b, and an insulating etch stop layer 170 covering the insulating isolation structure 165.

The device structure DS may include a data storage structure 172 for storing data in the memory cell region CA. The data storage structure 172 may include a cell capacitor for storing data in DRAM, for example, the lower electrodes 174, a dielectric layer 176 covering the lower electrodes 174, and an upper electrode 178 covering the dielectric layer 176.

The device structure DS may further include an interlayer insulating layer 183 covering the data storage structure 172 in the memory cell region CA, and covering the etch stop layer 170 in the peripheral circuit region PA. The device structure DS may further include a first contact structure 186 penetrating through the interlayer insulating layer 183 in the memory cell region CA and electrically connected to the upper electrode 178, and a second contact structure 187 penetrating through the interlayer insulating layer 183 and the etch stop layer 170 in the peripheral circuit region PA and electrically connected to the pad portion of the peripheral contact plug 160b.

The first contact structure 186 may include a contact plug 186b and a barrier layer 186a covering a side surface and a bottom surface of the contact plug 186b. Similarly, the second contact structure 187 may include a contact plug 187b and a barrier layer 187a covering a side surface and a bottom surface of the contact plug 187b.

Similarly to the aforementioned example embodiment, a wiring structure including a lower wiring structure LS and an upper wiring structure US stacked in order may be provided on the device structure DS.

The lower wiring structure LS employed in the example embodiment may include first to third lower insulating layers 22, 32, and 42, and first to third lower wiring layers 25 and 35, and 45 disposed in the first to third lower insulating layers 22, 32, and 42, respectively. The lower wiring structure LS may further include a first etch stop layer 21 provided between the interlayer insulating layer 12 and the first lower insulating layer 22, a second etch stop layer 31 provided between the first and second lower insulating layers 22 and 32, and a third etch stop layer 41 provided between the second and third lower insulating layers 32 and 42. Similarly to the first and second lower wiring layers 25 and 35, the third lower wiring layer 45 may also include a wiring pattern 45L and a via 45V extending downwardly from the wiring pattern 45L.

In the lower wiring structure LS, the first lower wiring layer 25 may be connected to the first and second contact structures 186 and 187 through the via 25V thereof, the second lower wiring layer 35 may be connected to the first lower wiring layer 25 through the via 35V thereof, and the third lower wiring layer 45 may be connected to the second lower wiring layer 35 through the via 45V thereof.

The upper structure US may be provided on the lower wiring structure LS. The upper structure US employed in the example embodiment may include first upper insulating layers 52 provided on the second lower insulating layer 32, upper contact 55 penetrating through the first upper insulating layers 52 and connected to the second lower wiring layer 35, an upper wiring layer 65 disposed on the first upper insulating layers 52 and connected to the upper contact, and a second upper insulating layer 62 disposed on the first upper insulating layers 52 and covering the upper wiring layer 65. The upper structure US may further include an etch stop layer 51 between the second lower insulating layer 32 and the first upper insulating layer 52. The upper contact 55 may penetrate through the first upper insulating layers 52 and the etch stop layer 51 and may be connected to the second lower wiring layer 32. The upper contact 55 may be electrically connected to each of devices of the device structure DS through the first and lower wiring layers 25 and 35 and the lower contacts 13 (see lower contact in FIG. 2B).

In the example embodiment, the upper wiring layer 65 may be connected to the upper contact 55 in the second upper insulating layers 62. A conductive bonding layer 61 may be disposed below the upper wiring layer 65. Differently from the aforementioned example embodiment, an anti-reflective layer may not be present on the upper wiring layer 65. For example, when the anti-reflective layer used during the patterning process is an organic material, the layer may be removed during the process and the upper surface of the upper wiring layer 65 may be exposed.

In the example embodiment, the Al alloy for the upper wiring layer 65 may include a dopant such as Zn, Ni, V, and Cr in the range of 0.01-3 wt %. In some example embodiments, the Al alloy of the upper wiring layer 65 may include a first dopant ED of at least one of Zn and Ni, and a second dopant SD of at least one of V and Cr. In the Al alloy of upper wiring layer 65 according to the example embodiment, the first dopant may be contained at 0.01-1.5 wt %, and the second dopant may be contained at 0.01-1.5 wt %. Here, the first dopants may be Zn and Ni, which may not be precipitated in the Al matrix, may maintain the α-phase, and may be highly likely to segregate into the grain boundary GB to improve EM. The second dopants may include V and Cr which may not be precipitated in the Al matrix, may maintain the α-phase of Al, and may be stably present in grains G in the form of a substitutional alloy to improve SM. The second dopants may have low diffusivity in Al and may not be segregated to the grain boundary.

According to the aforementioned example embodiments, by selecting an appropriate dopant which may not be precipitated in the Al matrix according to segregation tendency at the grain boundary, electro-migration (EM) and stress migration (SM) reliability of the upper wiring layer including Al may be effectively improved.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a substrate including devices;
a lower insulating layer on the substrate;
a lower wiring layer on the lower insulating layer and electrically connected to the devices;
a first upper insulating layer on the lower insulating layer;
an upper contact penetrating through the first upper insulating layer and connected to the lower wiring layer;
an upper wiring layer on the first upper insulating layer and connected to the upper contact; and
a second upper insulating layer on the first upper insulating layer and covering the upper wiring layer, wherein
the upper wiring layer includes an aluminum alloy,
0.01-3 wt % of the aluminum alloy is at least one dopant among Zn, Ni, V, and Cr, and
a balance of the aluminum alloy includes Al.

2. The semiconductor device of claim 1, wherein the at least one dopant includes at least one of Zn and Ni and at least one of V and Cr.

3. The semiconductor device of claim 1,
wherein the lower wiring layer includes copper (Cu), and
wherein the upper contact includes tungsten (W).

4. The semiconductor device of claim 1, wherein the at least one dopant includes 0.01-1 wt % of Zn.

5. The semiconductor device of claim 1, wherein the at least one dopant includes 0.01-0.24 wt % of Ni.

6. The semiconductor device of claim 1, wherein the at least one dopant includes 0.01-0.6 wt % of V.

7. The semiconductor device of claim 1, wherein the at least one dopant includes 0.01-0.7 wt % Cr.

8. The semiconductor device of claim 1, further comprising:
a conductive bonding layer between the upper wiring layer and the first upper insulating layer.

9. The semiconductor device of claim 8, wherein the conductive bonding layer includes one of Ti, Ta, Ru, TiN, TiSiN, TiAlx, TaN, and WN.

10. The semiconductor device of claim 1, further comprising:
an anti-reflective layer on the upper wiring layer.

11. The semiconductor device of claim 10, wherein the anti-reflective layer includes TiN or TaN.

12. The semiconductor device of claim 1, wherein
the lower wiring layer includes a wiring pattern and a via extending downwardly from the wiring pattern, and
the lower insulating layer covers a lower surface of the wiring pattern and a side surface of the wiring pattern, and
the via penetrates through a portion of the lower insulating layer, and
the portion of the lower insulating layer is on the lower surface of the wiring pattern.

13. The semiconductor device of claim 1, further comprising:
a lower etch stop layer on a lower surface of the lower insulating layer,
wherein a via of the lower wiring layer penetrates through the lower etch stop layer.

14. The semiconductor device of claim 13, further comprising:
an upper etch stop layer below the first upper insulating layer.

15. The semiconductor device of claim 1, wherein a dielectric constant of the lower insulating layer is lower than a dielectric constant of the first upper insulating layer.

16. The semiconductor device of claim 1, wherein
an inclined surface of the lower wiring layer is inclined downwardly,
an inclined surface of the upper contact is inclined downwardly, and
an inclined surface of the upper wiring layer is inclined upwardly.

17. A semiconductor device, comprising:
a substrate including a memory cell region and a peripheral circuit region;
capacitors on the memory cell region of the substrate;
peripheral transistors on the peripheral circuit region of the substrate;
an interlayer insulating layer covering the capacitors and the peripheral transistors on the substrate;
lower contacts in the interlayer insulating layer, the lower contacts electrically connected to the capacitors and the peripheral transistors;
a lower insulating layer on the interlayer insulating layer;
a lower wiring layer on the lower insulating layer and electrically connected to the lower contacts;
a first upper insulating layer on the lower insulating layer;
an upper contact penetrating through the first upper insulating layer and connected to the lower wiring layer;
an upper wiring layer on the first upper insulating layer and connected to the upper contact; and
a second upper insulating layer on the first upper insulating layer and covering the upper wiring layer, wherein
the upper wiring layer includes an aluminum alloy,
0.01-3 wt % of the aluminum alloy is at least one dopant among Zn, Ni, V, and Cr, and
a balance of the aluminum alloy includes Al.

18. The semiconductor device of claim 17, wherein
the at least one dopant of the upper wiring layer includes at least one of Zn and Ni and at least one of V and Cr.

19. The semiconductor device of claim 17, wherein
the lower insulating layer includes a plurality of lower insulating layers stacked in order on the interlayer insulating layer,
the lower wiring layer is includes a plurality of lower wiring layers connected to each other, and
the plurality of lower wiring layers are on the plurality of lower insulating layers, respectively.

20. A semiconductor device, comprising:
a substrate including devices;
an interlayer insulating layer covering the devices on the substrate;
a lower contact on the interlayer insulating layer and connected to the devices;
a lower insulating layer on the substrate;
a lower wiring layer on the lower insulating layer and connected to the lower contact;
a first upper insulating layer on the lower insulating layer;
an upper contact penetrating through the first upper insulating layer and connected to the lower wiring layer;
a second upper insulating layer on the first upper insulating layer; and
an upper wiring layer on the second upper insulating layer and connected to the upper contact, wherein
the upper wiring layer includes an aluminum alloy,
0.01-1.5 wt % of the aluminum alloy is a first dopant among at least one of Zn and Ni,
0.01-1.5 wt % of the aluminum alloy is a second dopant among at least one of V and Cr, and
a balance of the aluminum alloy includes Al.
